(19) United States
(12) Patent Application Publication
(10) Pub. No.: US 2021/0175402 A1
(43) Pub. Date: Jun. 10, 2021

(54) Thermoelectric Device with Flexible Heatsink

(71) Applicants: Jaeyoo Choi, (US); Jeffrey J. Urban, Berkeley, CA (US); Tintoria Piana, US Inc., Cartersville, GA (US)

(72) Inventors: Jaeyoo Choi, Richmond, CA (US); Sang-hoon Lim, Kennesaw, GA (US); Jeffrey J. Urban, Emeryville, CA (US); Andy Hollis, White, GA (US); Andrea Piana, Atlanta, GA (US)

(21) Appl. No.: 16/709,412

(22) Filed: Dec. 10, 2019

(51) Int. Cl. H01L 35/32; H01L 35/02; H01L 23/427; A41D 20/00

(52) U.S. Cl. CPC H01L 35/32; A41D 20/005; H01L 23/427; H01L 35/02

(57) ABSTRACT

A thermoelectric device suitable for power generation by the Seebeck effect or heating and cooling by the Peltier effect includes a flexible thermoelectric layer with a flexible heatsink layer. A thermally conductive layer can optionally be included on the side of the thermoelectric layer opposite the flexible heatsink layer. Because of its flexibility and durability, the thermoelectric device can be utilized for products such as a thermoelectric generator or cooling/heating system for consumer products, such as a bedding, clothing, hats, seat cushions, and personal portable devices.

### STATEMENT OF GOVERNMENT SUPPORT

This invention was made with government support under Contract No. DE-AC02-05CH11231 awarded by the U.S. Department of Energy. The government has certain rights in this invention.

### FIELD OF THE INVENTION

Embodiments described herein relate to thermoelectric devices, and particularly to a new flexible thermoelectric device with a flexible heatsink and its method of manufacturing.

### BACKGROUND

Thermoelectric (TE) devices can directly convert heat to electricity or electricity to heat/cooling. TE devices are sometimes referred to as Peltier devices, when operating in a cooling mode. In power generation mode, when a thermal gradient is applied to a TE material, electronic charges spontaneously flow from the hot region to the cold region. This produces a current with a voltage potential (ΔV) that arises across the material via the “Seebeck effect”. Conversely, if a current is applied to the TE material, exothermic and endothermic reactions can occur at the semiconductor-metal junctions via the “Peltier effect”. Because of these attributes, TE devices can effectively modulate temperature without any moving parts such as compressors, fans, or coolants.

Generally, a TE module consists of pairs of n- and p-type semiconducting materials, known as TE couples. A practical TE device consists of multiple pairs of p-type legs and n-type legs. This is because TE performance can be maximized when many TE couples are arranged electrically in series and thermally in parallel. Currently, there are commercial TE devices available on the market and extensive effort has been spent on designing and optimizing these modules over the last few decades. These devices have only recently reached sufficient power capacities when producing energy, and as solid-state cooling devices, but they are all currently composed of rigid, brittle, and inorganic materials.

Recently, with the advent of high performing soft organic materials, extensive research has been ongoing into exploring new possibilities for device optimization for this new class of materials. However, the organic TE materials show much lower performance when compared to current inorganic TE modules.

### SUMMARY OF THE INVENTION

Embodiments described herein pertain to a configuration for a new flexible thermoelectric device with a flexible heatsink. Current commercialized TE devices, which are composed of rigid, brittle, inorganic materials, are not suitable for flexible/wearable applications such as a power generation for geometrically complicated surfaces, energy harvesting from body heat, and/or thermal modulation to human skin, etc. When utilizing TE device for flexible applications, it is necessary to carefully design the whole system, including the selection of materials, the fabrication, and the design of a TE device.

In some embodiments, TE system includes a heatsink that can efficiently dissipate the unwanted heat. Heatsinks conduct thermal energy away from a heat-generating component to the environment by convection, radiation, or further conduction. Heatsinks usually have a large surface area to improve the heat dissipation. Aluminum (or other metals such as copper) extrusions are commonly used as heatsinks. These extrusions have rigid bases and extended surface areas with fin structures. In addition to their rigid bases, heatsinks are normally electrically conductive as well, using ceramics, metals, and sintered materials thus making them generally rigid as well. In contrast, and in one embodiment of the invention, such as used for wearable applications, a flexible heatsink consisting of soft, lightweight, durable, non-toxic materials is employed.

Various aspects of the embodiments of the invention have been devised in order to address issues of current TE devices, which include:

1. Commercial TE modules are rigid, thus not applicable for wearable or flexible uses.

2. A TE module without a heatsink can't maintain its performance consistently because the net thermal energy increases gradually via Joule heating or TE heating.

3. A heatsink to solve the issue presented in item 2 above, typically consists of metals, which are unusable in wearable, flexible, and portable applications because of the high weight and lack of flexibility.

4. Some manufacturing processes which might be used for a flexible TE device are complicated and high cost.

In particular, embodiments of the new flexible TE device with flexible heatsink and optional thermally conductive layer, generally are configured with the following in mind:

1. The TE layer is the core system for generating electricity or TE cooling/heating.

2. The flexible heatsink is used to maintain a consistent temperature gradient of the TE layer.

3. The optional thermally conductive layer is used for spreading heating or cooling efficiently.

In a particular embodiment, the TE layer is designed with multiple small blocks of commercial TE modules (Peltier modules) and a flexible supporting unit. For cost-effective and facile fabrication, for example, commercial TE modules are embedded into a flexible supporting material, which includes but is not limited to polydimethylsiloxane (PDMS) or Ecoflex® silicone. Due to the high flexibility and durability of the supporting materials, the whole TE module layer is also flexible to both parallel and perpendicular directions and mechanically durable even under the bending strain and compression stress.

The flexible heatsink preferably has multiple properties including flexibility, durability, lightweight, high thermal conductivity, and large heat capacity. In order to fulfill these needs, the heatsink comprises a flexible material, a thermally conductive material, and a heat storage material. For example, a flexible material such as PDMS or Ecoflex® silicone can be utilized as a basic matrix. These are examples of flexible organosilicon compounds. It should be understood that other flexible materials may be used in various embodiments of the invention as long as they are flexible (e.g., sufficiently flexible so as to allow bending of the finished TE device by 10, 30, 45, 70, 90 or more degrees, etc.) and have low thermal conductivity. Examples include but are not limited to elastomers, polyurethanes, polyolefins, or the like. Phase-change materials (PCM) such as EnFinit® PCM 28 CPS powder can be added as a heat storage material. A PCM is a substance which releases/absorbs energy at phase transition to provide useful cooling/heating. EnFinit® PCM 28 CPS is an example of microcapsulated PCM that is commercially available. Other examples of PCMs include but are not limited to paraffin waxes, polyethyleneglycols, fatty acids and derivatives, polyalcohols and derivatives, or inorganic salt hydrates or other salts. In addition, carbon materials such as graphite powder, carbon nanotube, or graphene flake can be utilized as a thermally conductive material. The mechanical and thermal properties of the flexible heatsink can be easily adjustable by controlling the composition of each component.

The optional thermally conductive layer enables large-area heating or cooling through a suitable combination of the TE layer. In one embodiment, this layer can spread heating or cooling from small areas of TE module blocks to large surface areas of the thermally conductive layer. In order to achieve efficient thermal transport, highly thermal conductive films can be utilized. These include but are not limited to conductive silicone, graphite, carbon nanotube, or graphene film.

Embodiments of the invention may be utilized for the improved efficiency and working time of TE devices. Embodiments of the invention can be used for energy harvesting from waste heat and/or as a thermoelectric heating/cooling system.

### BRIEF DESCRIPTION OF DRAWINGS

FIG. 1 is a schematic end view and side-view of a TE device with a flexible heatsink and a thermally conductive layer.

FIG. 2 is a top-view structure of the TE layer.

FIG. 3 illustrates two examples of the wearable TE device.

FIG. 4 is a graph showing the short-term cooling performance of the TE device with and without the flexible heatsink.

FIG. 5 illustrated the long-term cooling performance of the TE device with the flexible heatsink.

### DETAILED DESCRIPTION

FIG. 1 shows that the flexible TE device comprises a TE layer 1, a flexible heatsink layer 2, and an optional thermally conductive layer 3. Each layer can be produced simultaneously, or individual layers can be bonded together after fabrication. Simultaneous formation and/or bonding separate layers together achieves good thermal contact and mechanical durability. To achieve good contacts between each layer, in one embodiment, thermally conductive adhesives or tapes may be used. In one embodiment, the TE layer 1 and the flexible heatsink 2 can be made using the same flexible materials to help to guarantee good contact and bonding.

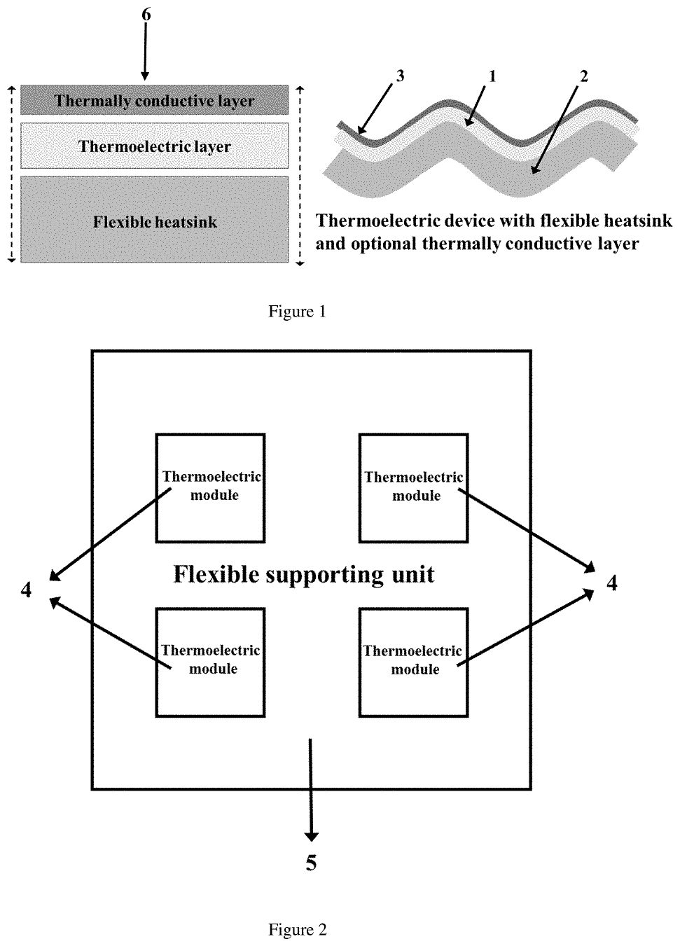

Referring to FIG. 2, the flexible TE layer 1 can be made of multiple, small-size commercial TE (Peltier) modules 4 embedded in flexible material which functions as a flexible supporting unit 5. The flexible material may be PDMS or Ecoflex® or another suitable material. The size of TE module 4 can vary depending on the final application. A preferred dimension of the TE module 4 is 15 mm×15 mm×5 mm or smaller. The TE layer 1 can be altered and be embodied in other variations.

Referring back to FIG. 2, in some embodiments, the flexible heatsink 2 is an important part for real-world applications, as it preferably has or satisfies multiple properties including flexibility, durability, low weight, high thermal conductivity, and large heat capacity. In one embodiment, the flexible heatsink 2 can be manufactured as a multi-component composite material comprising a flexible material, a thermally conductive material, and a heat storage material. For example, in some embodiments, the flexible material may be PMDS or Ecoflex® silicone. This flexible material can be utilized as a basic matrix and can be mixed with heat storage materials such as phase-change materials, which include but are not limited to EnFinit® PCM 28 CPS powder. The high thermally conductive materials include but are not limited to carbon materials such as graphite powder, carbon nanotube, or graphene flake. These carbon materials can be added to improve the heatsink performance. It should be noted that embodiments of the invention are not limited to the above materials. In some cases, component materials can be replaced with other desirable materials for specific applications.

In one embodiment, to guarantee constant material properties of the TE device layer 1 and the flexible heat sink 2, liquid-curable flexible materials such as PDMS or Ecoflex® silicone are preferred. They can be used to create a specific shape of a heatsink, such as circular, rectangular, fin-shaped geometries. Any other flexible materials may also be utilized as a matrix for a TE device in accordance with the practice of various embodiments of the invention. These materials can be any material with sufficient flexibility to allow for bending of the finished TE device. In some embodiments, a flexible matrix can be sufficiently flexible to form a bend of at least 10 degrees, a bend of at least 30 degrees, a bend of at least 45 degrees, a bend of at least 70 degrees, or a bend of at least 90 degrees (e.g. 120 or 180 degrees). Such flexibility likewise will preferably apply to the finished flexible TE device.

To fabricate a homogeneous product, a mechanical mixer or homogenizer can be utilized to mix each component. In some embodiments, the mechanical flexibility, durability, and thermal conductivity of the heatsink 2 can be adjusted by changing one or more or each component of the composition. For example, an increase of the flexible material in the composition will improve its mechanical durability and flexibility of layer, and an increase of the heat storage material or the thermally conductive material in the composition can improve the heat capacity or thermal conductivity of the heatsink 2, respectively.

With reference back to FIG. 1, thermally conductive layer 3 can be provided for the efficient spread of heating or cooling through the entire surface (i.e., the top surface 6, which may be a skin contacting surface for a wearable, etc.). Examples, of thermally conductive materials suitable for layer 3 include but are not limited to conductive silicone, graphite, carbon nanotube, or graphene films. If the thermally conductive layer 3 is not included in the TE device, the top surface would be the TE layer 1 itself.

In order to increase or decrease the targeting cooling or heating performance of the present TE device, in some embodiments, the degree of applied current to TE device can be adjustable. For example, by both the adoption of a higher-performing TE module and an increase in applied current, the degree of cooling or heating can be enhanced. The heating or cooling mode can also be switched through changing the direction of current.

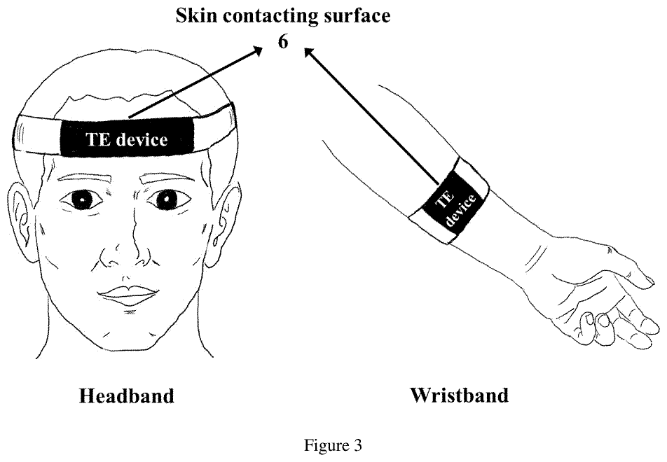

In addition, embodiments of the invention are not limited to cooling or heating applications but can also be used to generate electricity directly via Seebeck effect, thereby also enabling this device design to be used as a wearable TE device, for example. For the electrical generation mode, a thermally conductive layer 3 preferably faces the heat source, i.e., referring to FIG. 3, the top surface 6 contacts the heat source (e.g., person's skin, etc.), and the flexible heatsink layer 2 preferably faces the opposite direction to dissipate heat. Because the generation power by the TE layer 1 gradually decreases when the temperature gradient between the top and bottom side of TE layer 1 decreases, a thermally conductive layer and flexible heatsink are required to maintain the consistent working performance of TE device during long-term uses.

FIG. 3 shows some examples of wearable TE devices with a flexible heatsink and a thermally conductive layer 6. In particular, if cooling (or heating) for person's head (or other body part) is desired, a headband (or hat, or helmet, etc.) could have TE device with the thermally conductive layer adjacent the user's forehead (or other body part) for selective heating or cooling using the Peltier effect. In another embodiment, if energy harvesting is desired by the Seebeck effect, the TE device could be made as part of a wearable that attaches to a body part. For example, a wristband might be affixed to the user's arm (or other body part) which has a TE device having a thermally conductive layer 6 facing the user's skin. While wearing, the TE device can harvest energy from the user's body heat. The present TE device is not limited to headband or wristband types of wearable device, but can also be similarly utilized for consumer products, such as a bedding, clothing, hats, seat cushions, personal portable devices, etc.

### Example 1

A prototype flexible TE device was prepared by combining a TE layer and a heatsink layer. To make the TE layer, a commercial TE (Peltier) module (15 mm×15 mm×5 mm) was embedded in Ecoflex® silicone rubber. The heatsink layer was made by blending Ecoflex® silicone rubber (55 wt %), graphite powder (30 wt %), and EnFinit® PCM 28 CPS powder (15 wt %). 0.75 Voltage was applied to the TE device and the temperature of the cold surface of the device was measured with time. For comparison, the temperature of the same TE layer without the heatsink was measured.

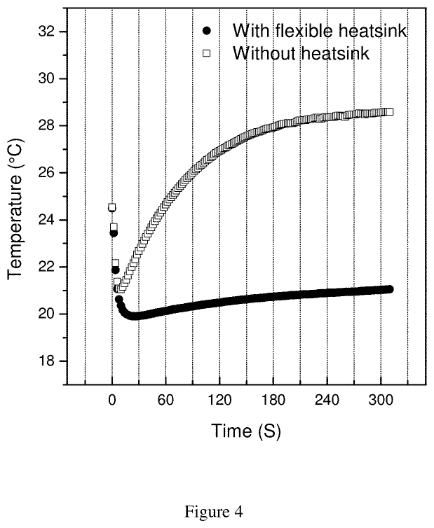

FIG. 4 shows the short-term cooling performance of the TE layer with and without the heatsink. Without the heatsink, the TE layer could not keep cooling more than 60 seconds, whereas the TE layer with heatsink kept cooling below the initial temperature by around 4° C. for over 300 seconds.

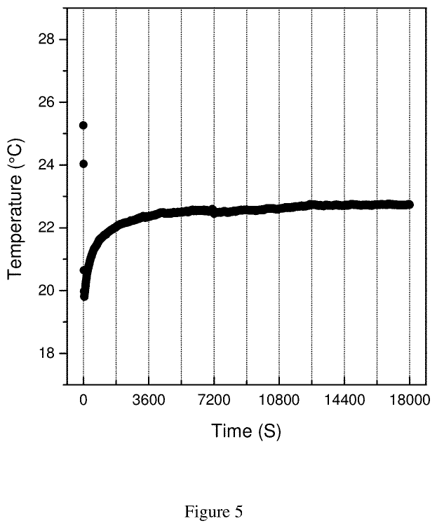

FIG. 5 shows the long-term cooling performance of the TE layer with the heatsink. It is shown that around 3° C. cooling was kept during 5 hours of testing.

1. A thermoelectric (TE) device comprising:
a thermoelectric layer including one or more thermoelectric modules embedded in a flexible substrate, said thermoelectric layer having a first and second side; and
a flexible heatsink layer bonded to the first side of the thermoelectric layer or integrally formed with the thermoelectric layer on the first side of the thermoelectric layer.

2. The TE device of claim 1 wherein the one or more thermoelectric modules in the thermoelectric layer includes a plurality of thermoelectric modules.

3. The TE device of claim 1 wherein the flexible heatsink layer is comprised of a flexible material, a thermally conductive material, and a heat storage material.

4. The TE device of claim 3 wherein the thermally conductive material is a carbon material.

5. The TE device of claim 4 wherein the carbon material is selected from the group consisting of graphite powder, carbon nanotube, and graphene flake.

6. The TE device of claim 3 wherein the heat storage material is a phase change material.

7. The TE device of claim 6 wherein the phase change material is selected from the group consisting of paraffin waxes, polyethyleneglycols, fatty acids and derivatives, polyalcohols and derivatives, and inorganic salt hydrates and other salts.

8. The TE device of claim 6 wherein the phase change material is microcapsulated.

9. The TE device of claim 3 wherein the flexible material is selected from the group consisting of a silicone rubber, an elastomer, a polyurethane, and a polyolefin.

10. The TE device of claim 1 further comprising a thermally conductive layer either bonded to the second side of the thermoelectric layer or integrally formed on the second side of the thermoelectric layer.

11. The TE device of claim 10 wherein the thermally conductive layer is selected from the group consisting of conductive silicone films, graphite films, carbon nanotube films, graphene films, and conductive polymer films.

12. The TE device of claim 10 configured as a wearable Peltier device.

13. The TE device of claim 12 wherein a wearable Peltier device is configured for positioning the thermally conductive layer on a portion of skin of a user.

14. The TE device of claim 10 configured as a wearable thermoelectric generator.

15. The TE device of claim 14 wherein the wearable thermoelectric generator is configured for positioning the thermally conductive layer on a portion of skin of a user.
